(19) United States
(12) Patent Application Publication
(10) Pub. No.: US 2020/0363854 A1
(43) Pub. Date: Nov. 19, 2020

(54) SWITCHING ENERGY SOURCE FOR POWER RAIL TRANSIENT COMPENSATION

(71) Applicant: Hewlett Packard Enterprise Development LP, Houston, TX (US)

(72) Inventors: Mohamed Amin Bemat, Houston, TX (US); Daniel Humphrey, Houston, TX (US); David Zhang, Houston, TX (US)

(21) Appl. No.: 16/410,950

(22) Filed: May 13, 2019

(51) Int. Cl. G06F 1/30; G05F 1/613; G01R 19/165; H02M 3/158

(52) U.S. Cl. CPC G06F 1/305; H02M 3/158; G01R 19/165; G05F 1/613

(57) ABSTRACT

Systems and switching energy sources are provided for power rail transient compensation. One system includes a voltage regulator having an output coupled to a power rail; a switching energy source configured to provide a determined amount of energy to the power rail responsive to a current transient on the power rail exceeding a determined rate of change; and a timer circuit configured to turn off the switching energy source a determined interval after the switching energy source begins to provide the determined amount of energy to the power rail.

### DESCRIPTION OF RELATED ART

The disclosed technology relates generally to power supplies, and more particularly some embodiments relate to voltage regulators and voltage regulation.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1 illustrates a voltage regulation system according to some embodiments of the disclosed technology.

FIG. 2 illustrates a voltage regulating system that includes a rapid power rail transient detector according to some embodiments of the disclosed technology.

FIG. 3 illustrates a voltage regulation system where the voltage regulator provides the enable signal according to some embodiments of the disclosed technology.

FIG. 4 illustrates a voltage regulation system where the load provides the enable signal according to some embodiments of the disclosed technology.

FIG. 5 illustrates a voltage regulation system according to some embodiments of the disclosed technology.

FIG. 6 is a block diagram of an example computing component or device for doing the invention in accordance with one embodiment.

FIG. 7 depicts a block diagram of an example computer system in which embodiments described herein may be implemented.

The figures are not exhaustive and do not limit the present disclosure to the precise form disclosed.

### DETAILED DESCRIPTION

Modern computing devices, such as computer servers and the like, place strict demands upon their power supplies. In particular, voltage regulators are required to compensate for transients, such as current transients, on the power rails providing power to the servers. But the servers and their processors are becoming increasingly complex. For example, the number of transistors in these processors is increasing rapidly. Consequently, transients on the power rails are becoming increasingly severe. In particular, the rates of change of these transients are increasing rapidly. The converter bandwidth of current voltage regulators are too low to compensate for these rapid transients. Loads such as processors may include capacitor banks to compensate for some rapid transients. However, as processors become increasingly complex, they require more pins, leaving less real estate for capacitors.

Embodiments of the disclosed technology provide independent switching energy sources to operate alongside main voltage regulators. Responsive to detecting a rapid transient on a power rail fed by the voltage regulator, the independent switching energy source injects a fixed burst of energy into the power rail, thereby compensating for the power rail transient. These independent switching energy sources include one or more features that allow them to compensate for power rail transients that occur too rapidly for current voltage regulators to compensate. These features may include one or more of low input power voltages, high switching frequencies, low inductances, non-interleaved phases, no feedback, and the like. These features allow the independent switching energy source to compensate for high speed power transients that the main voltage regulator cannot compensate.

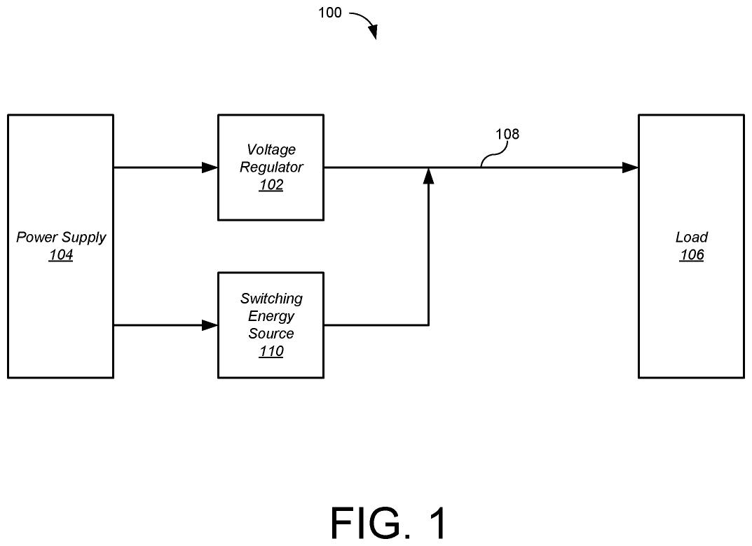

FIG. 1 illustrates a voltage regulation system according to some embodiments of the disclosed technology. Referring to FIG. 1, the voltage regulation system 100 includes a voltage regulator 102. The voltage regulator 102 may be any voltage regulator. For example, the voltage regulator may be a switching regulator, a buck regulator, a boost regulator, a buck-boost regulator, or the like. The voltage regulator 102 receives input power from a power supply 104, and provides regulated power to a load 106 over a power rail 108. The load 106 may be any load. In some embodiments, the load 106 includes one or more processors.

The voltage regulation system 100 also includes a switching energy source 110. The switching energy source 110 receives power from the power supply 104. When a rapid current transient appears on the power rail 108, the switching energy source 110 provides a determined (i.e., fixed, set, or specified) amount of energy to the power rail 108. In this manner, the switching energy source 110 compensates for power rail transients that occur too rapidly for the voltage regulator 102 to compensate. As described below, the switching energy source 110 may provide the determined amount of energy to the power rail 108 responsive to an enable signal.

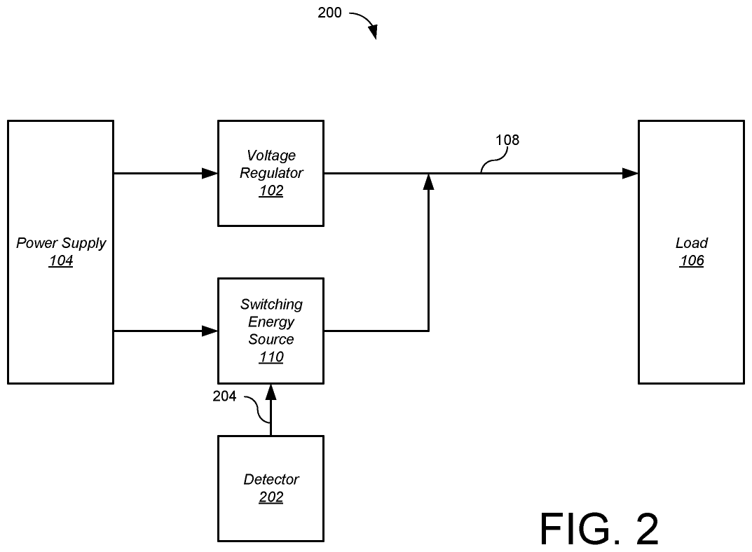

Some embodiments include a detector to detect rapid power rail transients. FIG. 2 illustrates a voltage regulating system that includes a rapid power rail transient detector according to some embodiments of the disclosed technology. Referring to FIG. 2, the voltage regulation system 200 includes the elements of the voltage regulation system 100 of FIG. 1. In addition, the voltage regulation system 200 of FIG. 2 includes a rapid power rail transient detector 202.

The detector 202 may sense rapid power rail transients directly on the power rail 108. For example, the detector 202 may sense a current transient on the power rail 108 having a current slew rate that exceeds a threshold current slew rate. As another example, the detector may sense a voltage transient on the power rail 108 having a voltage slew rate that exceeds a threshold voltage slew rate.

In some embodiments, the detector 202 may sense rapid power rail transients elsewhere. For example, the detector 202 may sense rapid power rail transients by monitoring a power input of the switching energy source 110. The detector may sense a current change, a voltage change, or both, occurring at a power input of the switching energy source 110. The change may include a change in level, a change in rate of change, the like, or combinations thereof. As another example, the detector 202 may sense rapid power rail transients by monitoring a power input of the voltage regulator 102. The detector may sense a current change, a voltage change, or both, occurring at a power input of the voltage regulator 102. The change may include a change in level, a change in rate of change, the like, or combinations thereof.

Responsive to detecting a rapid power rail transient, the detector 202 may provide an enable signal 204 to the switching energy source 110. Responsive to the enable signal, the switching energy source 110 may provide a determined (i.e., fixed, set, or specified) amount of energy to the power rail 108, thereby compensating for the rapid power rail transient.

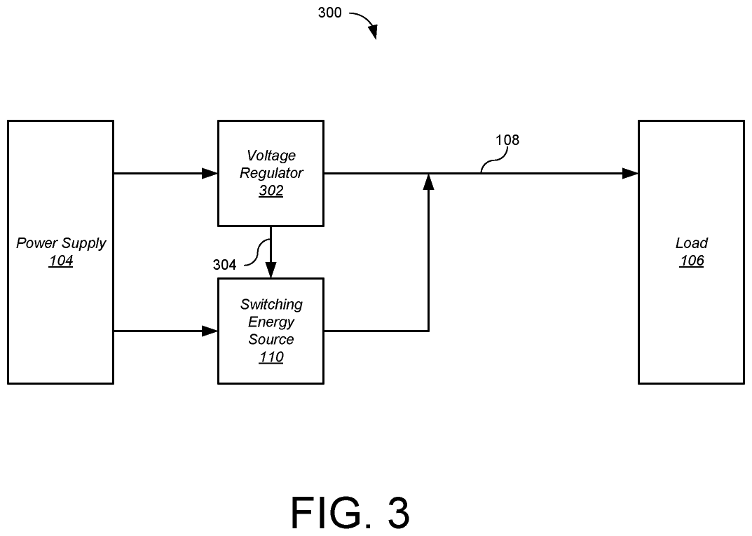

In some embodiments, the voltage regulator 102 may provide the enable signal to the switching energy source 110. FIG. 3 illustrates a voltage regulation system where the voltage regulator provides the enable signal according to some embodiments of the disclosed technology. Referring to FIG. 3, the voltage regulation system 300 includes the elements of the voltage regulation system 100 of FIG. 1, with the exception of the voltage regulator 102. In place of the voltage regulator 102 FIG. 1, the voltage regulation system 300 of FIG. 3 includes a voltage regulator 302 that is capable of providing an enable signal 304 responsive to rapid transients occurring on the power rail 108. Responsive to the enable signal 304, the switching energy source 110 may provide a determined amount of energy to the power rail 108, thereby compensating for the rapid power rail transient.

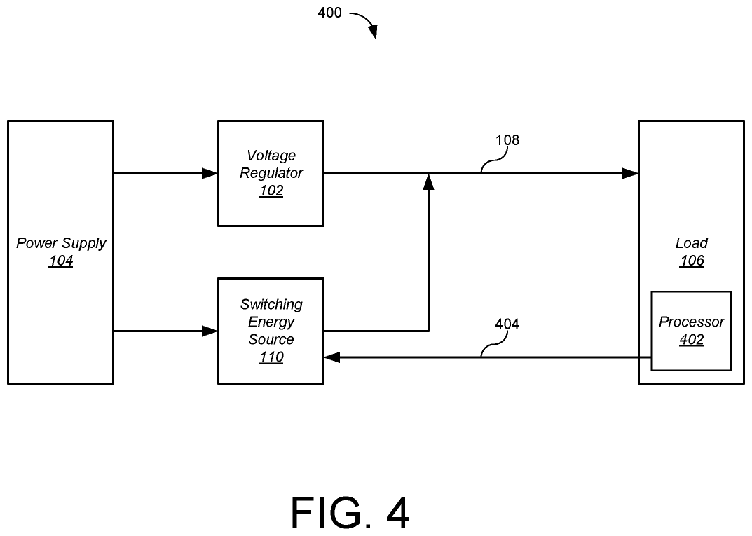

In some embodiments, the load 106 may provide the enable signal to the switching energy source 110. FIG. 4 illustrates a voltage regulation system where the load provides the enable signal according to some embodiments of the disclosed technology. Referring to FIG. 4, the voltage regulation system 300 includes the elements of the voltage regulation system 100 of FIG. 1. In addition, the load 106 includes a processor 402. The processor 402 may provide an enable signal 404 to the switching energy source 110. Responsive to the enable signal 404, the switching energy source 110 may provide a determined amount of energy to the power rail 108, thereby compensating for the rapid power rail transient. In the example of FIG. 4, the processor 402 may be the cause of the rapid power rail transient, may predict the rapid power rail transient, and may provide the enable signal 404 in anticipation of the rapid power rail transient.

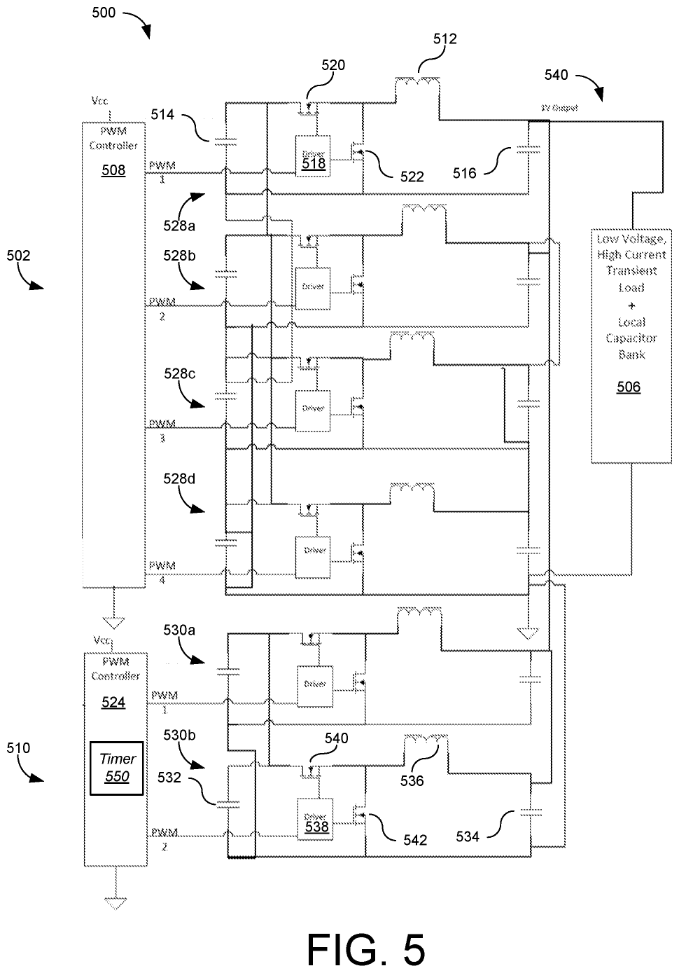

FIG. 5 illustrates a voltage regulation system according to some embodiments of the disclosed technology. Referring to FIG. 5, the voltage regulation system 500 may include a voltage regulator 502. The illustrated voltage regulator 502 is a four-phase buck regulator. But other embodiments may feature other voltage regulators with more or fewer phases and/or different regulator topologies. The voltage regulator 502 may include a pulse width modulation (PWM) controller 508 that may provide four switching inputs PWM1,2,3,4 to control four switching phases 528a,b,c,d, respectively. For conciseness of description, only one switching phase 528a is described.

Switching phase 528a may include a driver 518 that may drive a high-side metal-oxide semiconductor field-effect transistor (MOSFET) 520, and a low-side MOSFET 522, in accordance with the switching input PWM1. Switching phase 528a also may include an input capacitor 514, and an output capacitor 516, serving to smooth inputs and outputs, respectively. The MOSFETs 520, 522 may be coupled to the output capacitor 516 by an inductor 512. By appropriately varying the duty cycle of the switching inputs PWM1,2,3,4, the PWM controller 508 causes the switching phases 528a,b,c,d to maintain the output voltage close to a target value. The PWM controller 508 receives feedback (not illustrated) of the output voltage and/or output current, based upon which the controller 508 sets the duty cycle to appropriately regulate the output voltage.

The voltage regulation system 500 may include a switching energy source 510 comprising a PWM controller 524 and one or more switching phases 530 (in the example of FIG. 5, two switching phases 530a,b are illustrated, but any number may be included). The switching energy source may include a PWM controller 524 that may provide switching inputs to control the switching phases 530—for example, the two switching inputs PWM1,2 to control the two switching phases 530a,b, respectively. The switching phases 530 may have a similar topology as the switching phases 528 of the voltage regulator 502. Thus, the switching phases 530 may each include an input capacitor 532, an output capacitor 534, an inductor 536, a driver 538, a high-side MOSFET 540, and a low-side MOSFET 542.

Although similar components may be used in the switching phases 530 as are used in the switching phases 528, in some examples, at least some of the components of the switching energy source 510 may be smaller than and/or have different physical properties (e.g., capacitance, inductance) than the corresponding components of the voltage regulator 502. In particular, in some examples, the inductors 536 may be smaller and have lower inductance than the inductors 512. This reduction in component size may be beneficial in that it may free up expensive circuit board real estate. In addition, the lower inductance of the inductor 536 may allow for faster energy transfer to the load 506 with less energy storage. In some examples, the use of these smaller components may be enabled by the unique way in which the switching energy source 510 operates—for example, operating at a much higher switching frequency than the voltage regulator 502 (as described further below) and operating only during transients.

The switching energy source 510 also may receive a much lower voltage power input than the voltage regulator 502. For example, while the voltage regulator 502 may receive a 12 V power input, the switching energy source 510 may receive a 3.3 V power input. In some embodiments, the switching energy source 510 employs a fixed-frequency fixed duty cycle.

As noted above, the switching energy source 510 provides energy to the rail 540 only during transients, in contrast to the voltage regulator 502 which may output energy continuously. Moreover, when the switching energy source 510 does turn on to output energy, it injects a determined amount of energy and then turns off, in contrast to the voltage regulator 502 which may output an amount of energy that varies based on feedback. For example, an enable signal may be provided to the PWM controller 524 responsive to a transient occurring (or being anticipated), and the PWM controller 524 may cause the switching energy source 510 to begin outputting energy responsive to the enable signal and to cease outputting energy when the determined amount of energy has been provided.

More specifically, in some examples the switching energy source 510 may inject the determined amount of energy by turning on the switching energy source 510 for a set amount of time at a set duty cycle. For example, in some embodiments, the PWM controller 524 of the switching energy source 510 may include a timer 550 to limit the amount of energy delivered to the power rail 540. In some embodiments, the timer 550 may be programmed with a determined interval. The timer may be started when the switching energy source 510 begins to provide energy to the power rail 540 responsive to the transient, and when the determined interval expires, the PWM controller 524 may stop the supply of energy from the switching energy source 510 to the rail 540. More specifically, the PWM controller 524 may cause the switching phases 530a,b to begin the supplying of the fixed amount of energy by providing the switching inputs PWM1,2 at a fixed duty cycle to the drivers 538, and may cease supplying the energy by ceasing to supply the switching inputs PWM1,2.

Thus, in some examples the switching energy source 510 does not receive voltage or current feedback information (or if such information is received, it is not used by the PWM controller 524 to vary the duty cycle of its PWM switching input signals). Thus, the switching energy source 510 may be independent of the voltage regulator 502 at least in the sense that their switching signals (PWM signals) may have different duty cycles which are controlled based on different principles (fixed energy output irrespective of feedback versus variable output based on feedback). Furthermore, in some examples, the switching frequency of the switching inputs PWM1,2 of the switching energy source 510 is much higher than the switching frequency of the switching inputs PWM1,2,3,4 of the voltage regulator 502—for example, 3 Mhz for the switching energy source 510 versus 1 Mhz for the voltage regulator 502. In some examples, the switching inputs PWM1,2 of the switching energy source 510 are not interleaved (phase shifted), in contrast to the switching inputs PWM1,2,3,4 of the voltage regulator 502 which are usually interleaved (phase shifted).

The voltage regulation system 500 may include a load 506. Outputs of the voltage regulator 502, and the switching energy source 510, may be coupled to the load 506 by one or more power rails 540. The load 506 may include a local capacitor bank to compensate for some power rail transients. One advantage of the disclosed technology is that fewer and/or smaller capacitors are required because the switching energy source 510 compensates for many power rail transients.

The voltage regulator 502 represents one possible implementation example of the voltage regulators 102 and 103 described above. The switching energy source 510 represents one possible implementation example of the switching energy source 110 described above.

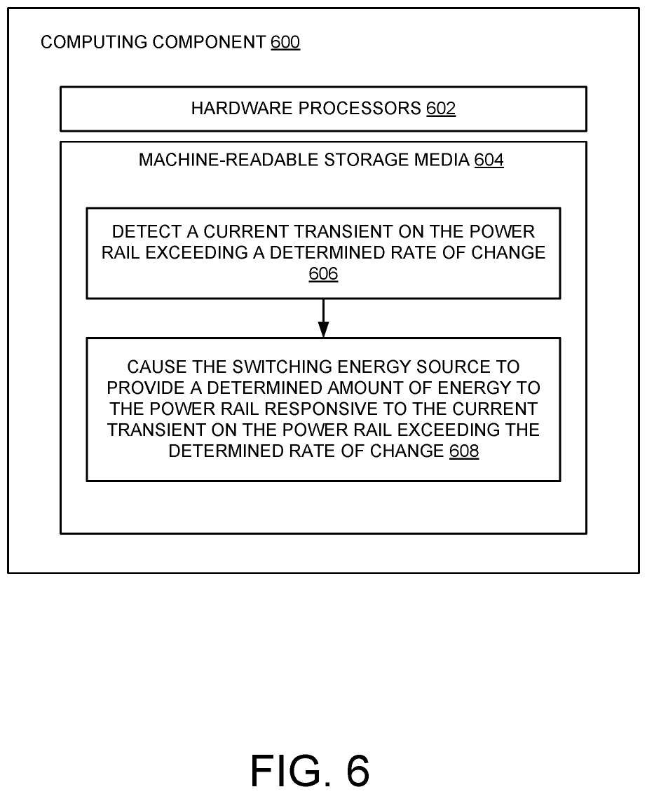

FIG. 6 is a block diagram of an example computing component or device for doing the invention in accordance with one embodiment. Computing component 600 may be, for example, a server computer, a controller, or any other similar computing component capable of processing data. In the example implementation of FIG. 6, the computing component 600 includes a hardware processor 602, and machine-readable storage medium 604.

In some embodiments, computing component 600 may be an embodiment of the PWM controller 524 of the switching energy source 510, the PWM controller 508 of the voltage regulator 502, a separate controller, or any combination thereof. Although the computing component 600 is described with reference to the voltage regulation system 500 of FIG. 5, this description may apply to other embodiments as well.

Hardware processor 602 may be one or more central processing units (CPUs), semiconductor-based microprocessors, and/or other hardware devices suitable for retrieval and execution of instructions stored in machine-readable storage medium, 604. Hardware processor 602 may fetch, decode, and execute instructions, such as instructions 606-608, to control processes or operations for voltage regulation. As an alternative or in addition to retrieving and executing instructions, hardware processor 602 may include one or more electronic circuits that include electronic components for performing the functionality of one or more instructions, such as a field programmable gate array (FPGA), application specific integrated circuit (ASIC), or other electronic circuits.

A machine-readable storage medium, such as machine-readable storage medium 604, may be any electronic, magnetic, optical, or other physical storage device that contains or stores executable instructions. Thus, machine-readable storage medium 604 may be, for example, Random Access Memory (RAM), non-volatile RAM (NVRAM), an Electrically Erasable Programmable Read-Only Memory (EEPROM), a storage device, an optical disc, and the like. In some embodiments, machine-readable storage medium 604 may be a non-transitory storage medium, where the term “non-transitory” does not encompass transitory propagating signals. As described in detail below, machine-readable storage medium 604 may be encoded with executable instructions, for example, instructions 606-608. Depending on the implementation, the instructions 606-608 may include additional, fewer, or alternative instructions performed in various orders or in parallel.

Hardware processor 602 may execute instruction 606 to detect a current transient on the power rail 540 exceeding a determined rate of change. For example, the detector 202 of the voltage regulation system 200 of FIG. 2 may detect the transient as described above, and provide an indication of the detection to the processor 602. In one example, the determined rate of change for the current transient on the power rail 540 may be 30 A/μs. The current transient may be detected directly on the power rail 540, or elsewhere in the voltage regulation system.

Hardware processor 602 may execute instruction 608 to cause the switching energy source 510 to provide a determined amount of energy to the power rail 540 responsive to the current transient on the power rail 540 exceeding the determined rate of change. For example, the processor 602 may cause the switching energy source 510 to turn on and output energy for a set amount of time at a set duty, as described above. In one example, the switching energy source 510 may operate at a frequency of 3 MHz and a 75% duty cycle for 500 μs.

The switching energy source 510 may not employ feedback. That is, the switching energy source 510 provides the determined amount of energy to the power rail 540 regardless of conditions on the power rail 540 following the current transient. These conditions including voltage levels, current levels, voltage rates of change, current rates of change, and the like. In some embodiments, the determined amount of energy may be limited using the timer 550 of the PWM controller 524.

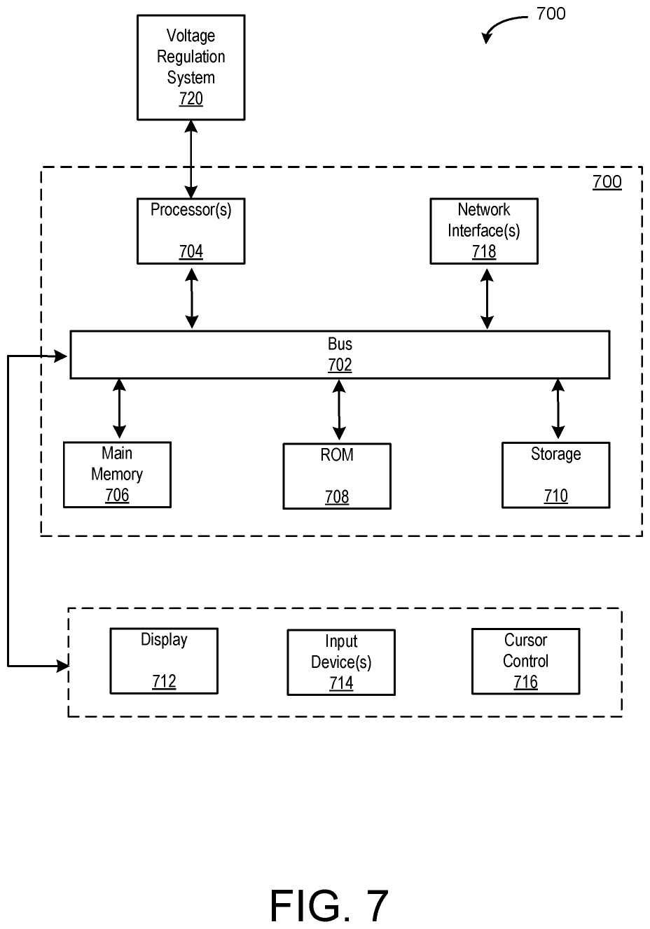

FIG. 7 depicts a block diagram of an example computer system 700 in which embodiments described herein may be implemented. The computer system 700 includes a bus 702 or other communication mechanism for communicating information, one or more hardware processors 704 coupled with bus 702 for processing information. Hardware processor(s) 704 may be, for example, one or more general purpose microprocessors.

The computer system 700 includes a voltage regulation system 720. The voltage regulation system 720 may be implemented, for example, as any one of the voltage regulation systems 100, 200, 300, 400, or 500 described above. The voltage regulation system 720 may provide power to elements of the example computer system 700. For example, voltage regulation system 720 may provide power to the hardware processor(s) 704.

The computer system 700 also includes a main memory 706, such as a random access memory (RAM), cache and/or other dynamic storage devices, coupled to bus 702 for storing information and instructions to be executed by processor 704. Main memory 706 also may be used for storing temporary variables or other intermediate information during execution of instructions to be executed by processor 704. Such instructions, when stored in storage media accessible to processor 704, render computer system 700 into a special-purpose machine that is customized to perform the operations specified in the instructions.

The computer system 700 further includes a read only memory (ROM) 708 or other static storage device coupled to bus 702 for storing static information and instructions for processor 704. A storage device 710, such as a magnetic disk, optical disk, or USB thumb drive (Flash drive), etc., is provided and coupled to bus 702 for storing information and instructions.

The computer system 700 may be coupled via bus 702 to a display 712, such as a liquid crystal display (LCD) (or touch screen), for displaying information to a computer user. An input device 714, including alphanumeric and other keys, is coupled to bus 702 for communicating information and command selections to processor 704. Another type of user input device is cursor control 716, such as a mouse, a trackball, or cursor direction keys for communicating direction information and command selections to processor 704 and for controlling cursor movement on display 712. In some embodiments, the same direction information and command selections as cursor control may be implemented via receiving touches on a touch screen without a cursor.

The computing system 700 may include a user interface module to implement a GUI that may be stored in a mass storage device as executable software codes that are executed by the computing device(s). This and other modules may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables.

In general, the word “component,” “engine,” “system,” “database,” data store,” and the like, as used herein, can refer to logic embodied in hardware or firmware, or to a collection of software instructions, possibly having entry and exit points, written in a programming language, such as, for example, Java, C or C++. A software component may be compiled and linked into an executable program, installed in a dynamic link library, or may be written in an interpreted programming language such as, for example, BASIC, Perl, or Python. It will be appreciated that software components may be callable from other components or from themselves, and/or may be invoked in response to detected events or interrupts. Software components configured for execution on computing devices may be provided on a computer readable medium, such as a compact disc, digital video disc, flash drive, magnetic disc, or any other tangible medium, or as a digital download (and may be originally stored in a compressed or installable format that requires installation, decompression or decryption prior to execution). Such software code may be stored, partially or fully, on a memory device of the executing computing device, for execution by the computing device. Software instructions may be embedded in firmware, such as an EPROM. It will be further appreciated that hardware components may be comprised of connected logic units, such as gates and flip-flops, and/or may be comprised of programmable units, such as programmable gate arrays or processors.

The computer system 700 may implement the techniques described herein using customized hard-wired logic, one or more ASICs or FPGAs, firmware and/or program logic which in combination with the computer system causes or programs computer system 700 to be a special-purpose machine. According to one embodiment, the techniques herein are performed by computer system 700 in response to processor(s) 704 executing one or more sequences of one or more instructions contained in main memory 706. Such instructions may be read into main memory 706 from another storage medium, such as storage device 710. Execution of the sequences of instructions contained in main memory 706 causes processor(s) 704 to perform the process steps described herein. In alternative embodiments, hard-wired circuitry may be used in place of or in combination with software instructions.

The term “non-transitory media,” and similar terms, as used herein refers to any media that store data and/or instructions that cause a machine to operate in a specific fashion. Such non-transitory media may comprise non-volatile media and/or volatile media. Non-volatile media includes, for example, optical or magnetic disks, such as storage device 710. Volatile media includes dynamic memory, such as main memory 706. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM, NVRAM, any other memory chip or cartridge, and networked versions of the same.

Non-transitory media is distinct from but may be used in conjunction with transmission media. Transmission media participates in transferring information between non-transitory media. For example, transmission media includes coaxial cables, copper wire and fiber optics, including the wires that comprise bus 702. Transmission media can also take the form of acoustic or light waves, such as those generated during radio-wave and infra-red data communications.

The computer system 700 also includes a communication interface 718 coupled to bus 702. Network interface 718 provides a two-way data communication coupling to one or more network links that are connected to one or more local networks. For example, communication interface 718 may be an integrated services digital network (ISDN) card, cable modem, satellite modem, or a modem to provide a data communication connection to a corresponding type of telephone line. As another example, network interface 718 may be a local area network (LAN) card to provide a data communication connection to a compatible LAN (or WAN component to communicate with a WAN). Wireless links may also be implemented. In any such implementation, network interface 718 sends and receives electrical, electromagnetic or optical signals that carry digital data streams representing various types of information.

A network link typically provides data communication through one or more networks to other data devices. For example, a network link may provide a connection through local network to a host computer or to data equipment operated by an Internet Service Provider (ISP). The ISP in turn provides data communication services through the world wide packet data communication network now commonly referred to as the “Internet.” Local network and Internet both use electrical, electromagnetic or optical signals that carry digital data streams. The signals through the various networks and the signals on network link and through communication interface 718, which carry the digital data to and from computer system 700, are example forms of transmission media.

The computer system 700 can send messages and receive data, including program code, through the network(s), network link and communication interface 718. In the Internet example, a server might transmit a requested code for an application program through the Internet, the ISP, the local network and the communication interface 718.

The received code may be executed by processor 704 as it is received, and/or stored in storage device 710, or other non-volatile storage for later execution.

Each of the processes, methods, and algorithms described in the preceding sections may be embodied in, and fully or partially automated by, code components executed by one or more computer systems or computer processors comprising computer hardware. The one or more computer systems or computer processors may also operate to support performance of the relevant operations in a “cloud computing” environment or as a “software as a service” (SaaS). The processes and algorithms may be implemented partially or wholly in application-specific circuitry. The various features and processes described above may be used independently of one another, or may be combined in various ways. Different combinations and sub-combinations are intended to fall within the scope of this disclosure, and certain method or process blocks may be omitted in some implementations. The methods and processes described herein are also not limited to any particular sequence, and the blocks or states relating thereto can be performed in other sequences that are appropriate, or may be performed in parallel, or in some other manner. Blocks or states may be added to or removed from the disclosed example embodiments. The performance of certain of the operations or processes may be distributed among computer systems or computers processors, not only residing within a single machine, but deployed across a number of machines.

As used herein, a circuit might be implemented utilizing any form of hardware, software, or a combination thereof. For example, one or more processors, controllers, ASICs, PLAs, PALs, CPLDs, FPGAs, logical components, software routines or other mechanisms might be implemented to make up a circuit. In implementation, the various circuits described herein might be implemented as discrete circuits or the functions and features described can be shared in part or in total among one or more circuits. Even though various features or elements of functionality may be individually described or claimed as separate circuits, these features and functionality can be shared among one or more common circuits, and such description shall not require or imply that separate circuits are required to implement such features or functionality. Where a circuit is implemented in whole or in part using software, such software can be implemented to operate with a computing or processing system capable of carrying out the functionality described with respect thereto, such as computer system 700.

As used herein, the term “or” may be construed in either an inclusive or exclusive sense. Moreover, the description of resources, operations, or structures in the singular shall not be read to exclude the plural. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps.

Terms and phrases used in this document, and variations thereof, unless otherwise expressly stated, should be construed as open ended as opposed to limiting. Adjectives such as “conventional,” “traditional,” “normal,” “standard,” “known,” and terms of similar meaning should not be construed as limiting the item described to a given time period or to an item available as of a given time, but instead should be read to encompass conventional, traditional, normal, or standard technologies that may be available or known now or at any time in the future. The presence of broadening words and phrases such as “one or more,” “at least,” “but not limited to” or other like phrases in some instances shall not be read to mean that the narrower case is intended or required in instances where such broadening phrases may be absent.

1. A circuit comprising:
a voltage regulator having an output coupled to a power rail; and
a switching energy source configured to provide a determined amount of energy to the power rail responsive to exceeding a determined rate of change for a current transient on the power rail,
wherein a first voltage of a power input of the switching energy source is lower than a second voltage of a power input of the voltage regulator.

2. The circuit of claim 1, further comprising:
wherein the switching energy source provides the determined amount of energy to the power rail regardless of conditions on the power rail following the current transient, the conditions including voltage levels, current levels, voltage rates of change, and current rates of change.

3. (canceled)

4. The circuit of claim 1, wherein:
a switching frequency of the switching energy source is higher than a switching frequency of the voltage regulator.

5. The circuit of claim 1, wherein:
the switching energy source includes multiple phases; and
each of the phases from the multiple phases are not interleaved.

6. The circuit of claim 1, wherein:
the switching energy source is further configured to provide the determined amount of energy to the power rail responsive to receiving an enable signal, wherein the enable signal is provided based on a detection of the determined rate of change by at least one of:
a processor coupled to the power rail;
the voltage regulator; and
a detector configured to detect the current transient.

7. The circuit of claim 1, further comprising:
a detector configured to detect rate of change for the current transient, and to provide an enable signal based on the exceeding of the determined rate of change;
wherein the switching energy source is further configured to provide the determined amount of energy to the power rail responsive to receiving the enable signal; and
wherein, to detect the rate of change for the current transient on the power rail, the detector senses at least one of:
the current transient on the power rail;
a voltage transient on the power rail;
a current change at a power input of the switching energy source;
a voltage change at the power input of the switching energy source;
a current change at a power input of the voltage regulator; and
a voltage change at the power input of the voltage regulator.

8. A circuit comprising:
a voltage regulator having an output coupled to a power rail; and
a switching energy source configured to provide a determined amount of energy to the power rail responsive to exceeding a determined rate of change for a current transient on the power rail; and
a timer circuit configured to turn off the switching energy source a determined time interval after the switching energy source begins to provide the determined amount of energy to the power rail,
wherein a first voltage of a power input of the switching energy source is lower than a second voltage of a power input of the voltage regulator.

9. The circuit of claim 8, further comprising:
wherein the switching energy source provides the determined amount of energy to the power rail regardless of conditions on the power rail following the current transient, the conditions including voltage levels, current levels, voltage rates of change, and current rates of change.

10. (canceled)

11. The circuit of claim 8, wherein:
a switching frequency of the switching energy source is higher than a switching frequency of the voltage regulator.

12. The circuit of claim 8, wherein:
the switching energy source includes multiple phases; and
each of the phases from the multiple phases are not interleaved.

13. The circuit of claim 8, wherein:
the switching energy source is further configured to provide the determined amount of energy to the power rail responsive to receiving an enable signal, wherein the enable signal is provided based on a detection of the determined rate of change by at least one of:
a processor coupled to the power rail;
the voltage regulator; and
a detector configured to detect the current transient.

14. The circuit of claim 8, further comprising:
a detector configured to detect a rate of change for the current transient, and to provide an enable signal based on the exceeding of the determined rate of change;
wherein the switching energy source is further configured to provide the determined amount of energy to the power rail responsive to receiving the enable signal; and
wherein, to detect the rate of change for the current transient on the power rail, the detector senses at least one of:
the current transient on the power rail;
a voltage transient on the power rail;
a current change at a power input of the switching energy source;
a voltage change at the power input of the switching energy source;
a current change at a power input of the voltage regulator; and
a voltage change at the power input of the voltage regulator.

15. A voltage regulation system comprising:
a voltage regulator having an output coupled to a power rail;
a switching energy source having an output coupled to the power rail;
a hardware processor; and
a non-transitory machine-readable storage medium encoded with instructions executable by the hardware processor to cause the hardware processor to:
detect a current transient on the power rail;
identify that the current transient is exceeding a determined rate of change; and
cause the switching energy source to provide a determined amount of energy to the power rail responsive to the identification,
wherein a first voltage of a power input of the switching energy source is lower than a second voltage of a power input of the voltage regulator.

16. The voltage regulation system of claim 15, wherein the instructions further cause the hardware processor to:
cause the switching energy source to provide the determined amount of energy to the power rail regardless of conditions on the power rail following the identification, the conditions including voltage levels, current levels, voltage rates of change, and current rates of change.

17. (canceled)

18. The voltage regulation system of claim 15, wherein:
a switching frequency of the switching energy source is higher than a switching frequency of the voltage regulator.

19. The voltage regulation system of claim 15, wherein:
the switching energy source includes multiple phases; and
each of the phases from the multiple phases are not interleaved.

20. The voltage regulation system of claim 15, wherein:
the switching energy source is further configured to provide the determined amount of energy to the power rail responsive to receiving an enable signal, wherein the enable signal is provided based on the identification by at least one of:
a processor coupled to the power rail;
the voltage regulator; and
a detector configured to detect the current transient.

21. The voltage regulation system of claim 15, further comprising:
a detector communicatively coupled to the hardware processor and configured to detect rate of change for the current transient to provide an enable signal based on the exceeding the determined rate of change;
wherein the switching energy source is further configured to provide the determined amount of energy to the power rail responsive to receiving the enable signal; and
wherein, to detect the rate of change for the current transient on the power rail, the detector senses at least one of:
the current transient on the power rail;
a voltage transient on the power rail;
a current change at a power input of the switching energy source;
a voltage change at the power input of the switching energy source;
a current change at a power input of the voltage regulator; and
a voltage change at the power input of the voltage regulator.
